(19) United States
(12) Patent Application Publication
(10) Pub. No.: US 2025/0279760 A1
(43) Pub. Date: Sep. 4, 2025

(54) BULK ACOUSTIC RESONATOR WITH VARYING THICKNESS IDT CONFIGURATION

(71) Applicant: Murata Manufacturing Co., Ltd., Nagaokakyo-shi (JP)

(72) Inventors: Albert CARDONA, Santa Barbara, CA (US); Sean MCHUGH, Santa Barbara, CA (US); Soumya YANDRAPALLI, Goleta, CA (US)

(21) Appl. No.: 19/061,759

(22) Filed: Feb. 24, 2025

Related U.S. Application Data
(60) Provisional application No. 63/559,755, filed on Feb. 29, 2024.

(51) Int. Cl. H03H 9/02; H03H 9/17; H03H 9/56

(52) U.S. Cl. CPC H03H 9/02157; H03H 9/02015; H03H 9/02228; H03H 9/175; H03H 9/568

(57) ABSTRACT

A bulk acoustic resonator, a filter device including the bulk acoustic resonator, and a radio frequency module including the filter device are provided. The bulk acoustic resonator includes a piezoelectric layer; and an IDT over a surface of the piezoelectric layer. The IDT includes first and second pluralities of interleaved fingers. A pair of subsections of the second plurality of interleaved fingers are disposed on opposing sides of the first plurality of interleaved fingers in a lengthwise direction of the IDT. A first thickness of the first plurality of interleaved fingers is different from a second thickness of the second plurality of interleaved fingers. Moreover, a first pitch of the first plurality of interleaved fingers is different from a second pitch of the second plurality of interleaved fingers.

### CROSS REFERENCE TO RELATED APPLICATIONS

This application claims priority to U.S. Provisional Application No. 63/559,755, filed Feb. 29, 2024, the entire contents of which are hereby incorporated by reference.

### TECHNICAL FIELD

This disclosure relates to radio frequency filters using acoustic wave resonators, and more specifically, to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate with mitigated spurs and enhanced power handling performance.

### SUMMARY

Thinner IDT fingers may be used in a bulk acoustic resonator to mitigate spurs in a filter passband. In some examples, using thinner IDT fingers may reduce power handling capability as compared to equivalent thick IDT fingers. According to an aspect of the disclosure, the power handling performance can be improved without introducing significant spurs by using a mixed thin-thick IDT where a small number of thin IDT fingers are replaced by thicker IDT fingers. Further, pitches of the thin IDT fingers and the thick IDT fingers in the mixed thin-thick IDT can be tuned and configured such that the mixed thin-thick IDT has a single resonance frequency at the main peak.

A bulk acoustic resonator, a filter device including the bulk acoustic resonator, and a radio frequency module including the filter device are provided. The bulk acoustic resonator includes a piezoelectric layer; and an interdigital transducer (IDT) over a surface of the piezoelectric layer, the IDT comprising a first plurality of interleaved fingers and a second plurality of interleaved fingers. In this aspect, the second plurality of interleaved fingers includes a pair of subsections of interleaved fingers that are disposed on sides of the first plurality of interleaved fingers in a lengthwise direction of the IDT. Moreover, the first plurality of interleaved fingers has a first thickness that is different than a second thickness of the second plurality of interleaved fingers, and the first thickness and the second thickness are each measured in a direction substantially orthogonal to the surface of the piezoelectric layer. Finally, a first pitch of the first plurality of interleaved fingers is different than a second pitch of the second plurality of interleaved fingers.

According to an exemplary aspect, the first thickness of the first plurality of interleaved fingers is greater than the second thickness of the second plurality of interleaved fingers.

According to another exemplary aspect, the first thickness of the first plurality of interleaved fingers is less than the second thickness of the second plurality of interleaved fingers.

According to another exemplary aspect, either the first thickness or the second thickness is greater than or equal to two times than the other of the first thickness and the second thickness.

According to another exemplary aspect, each respective section of the first pitch of the first plurality of interleaved fingers and the second pitch of the second plurality of interleaved fingers are chirped within each section at a variance that is less than a variance between the first pitch of the first plurality of interleaved fingers and the second pitch of the second plurality of interleaved fingers.

According to another exemplary aspect, the IDT comprises a first busbar and a second busbar that are disposed on the surface of the piezoelectric layer and extend along a first direction that is substantially orthogonal to a second direction in which the first plurality of interleaved fingers and the second plurality of interleaved fingers of the IDT extend. In this aspect, the second pitch of the second plurality of interleaved fingers can be between 12% to 20% larger than the first pitch of the first plurality of interleaved fingers. Moreover, in this aspect, the first busbar and the second busbar can have a convex shape, the first thickness of the first plurality of interleaved fingers can be greater than the second thickness of the second plurality of interleaved fingers, and an average length of the first plurality of interleaved fingers can be longer than an average length of the second plurality of interleaved fingers in the second direction. Yet further, in this aspect, the first busbar and the second busbar can have a concave shape, the first thickness of the first plurality of interleaved fingers can be less than the second thickness of the second plurality of interleaved fingers, and an average length of the first plurality of interleaved fingers can be shorter than an average length of the second plurality of interleaved fingers in the second direction.

According to another exemplary aspect, the piezoelectric layer comprises a diaphragm over a cavity, and the IDT is on the diaphragm, the piezoelectric layer and the IDT are configured such that a radio frequency signal applied to the IDT excites a bulk shear wave having a propagation direction perpendicular to a direction of a primarily laterally excited electric field generated by the IDT, and the electric field is primarily laterally excited when atomic motion of the bulk shear wave is primarily horizontal in the piezoelectric layer, while the bulk shear wave propagates in a direction primarily perpendicular to the direction of atomic motion.

According to another exemplary aspect, the piezoelectric layer is disposed over an acoustic Bragg reflector that includes multiple dielectric layers that alternate between materials having high acoustic impedance and materials having low acoustic impedance.

In yet another exemplary aspect, a filter device is provided that includes a plurality of bulk acoustic resonators connected in parallel, at least one acoustic resonator of the plurality of bulk acoustic resonators including a piezoelectric layer, and an interdigital transducer (IDT) over a surface of the piezoelectric layer, the IDT comprising a first plurality of interleaved fingers and a second plurality of interleaved fingers. In this aspect, the second plurality of interleaved fingers includes a pair of subsections of interleaved fingers that are disposed on sides of the first plurality of interleaved fingers in a lengthwise direction of the IDT, and a first thickness of the first plurality of interleaved fingers is different than a second thickness of the second plurality of interleaved fingers. Moreover, the first thickness and the second thickness are measured in a direction substantially orthogonal to the surface of the piezoelectric layer, and a first pitch of the first plurality of interleaved fingers is different than a second pitch of the second plurality of interleaved fingers.

In yet another exemplary aspect, a radio frequency module is provided that includes a filter device including a plurality of bulk acoustic resonators connected in parallel; and a radio frequency circuit coupled to the filter device, the filter device and the radio frequency circuit being enclosed within a common package. In this aspect, at least one acoustic resonator of the plurality of bulk acoustic resonators of the filter device includes a piezoelectric layer, and an interdigital transducer (IDT) over a surface of the piezoelectric layer, the IDT comprising a first plurality of interleaved fingers and a second plurality of interleaved fingers. Moreover, the second plurality of interleaved fingers includes a pair of subsections of interleaved fingers that are disposed on sides of the first plurality of interleaved fingers in a lengthwise direction of the IDT, and a first thickness of the first plurality of interleaved fingers is different than a second thickness of the second plurality of interleaved fingers. In this aspect, the first thickness and the second thickness are measured in a direction substantially orthogonal to the surface of the piezoelectric layer, and a first pitch of the first plurality of interleaved fingers is different than a second pitch of the second plurality of interleaved fingers.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 shows a cross-sectional view of a portion of an example of a bulk acoustic resonator including an IDT according to an exemplary aspect.

FIGS. 7-8 show top views of respective examples of the bulk acoustic resonator shown in FIG. 6 according to exemplary aspects.

FIG. 9 shows a cross-sectional view of a portion of an example of a bulk acoustic resonator including an IDT according to an exemplary aspect.

FIGS. 10-11 show top views of respective examples of the bulk acoustic resonator shown in FIG. 9 according to exemplary aspects.

FIG. 12 shows examples three bulk acoustic resonators having respective IDT configurations according to an exemplary aspect.

FIGS. 13A, 13B, 14A, and 14B compare the performance of the three bulk acoustic resonators shown in FIG. 12 according to an exemplary aspect.

FIG. 15 shows a zoomed-in view of two resonance frequencies of one of the bulk acoustic resonators shown in FIG. 12 according to an example of the disclosure.

FIG. 16A shows an example of a relationship between a resonance frequency and a pitch of an IDT according to an exemplary aspect.

FIG. 16B shows an example of a single resonance frequency of a mixed thin-thick IDT according to an exemplary aspect.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

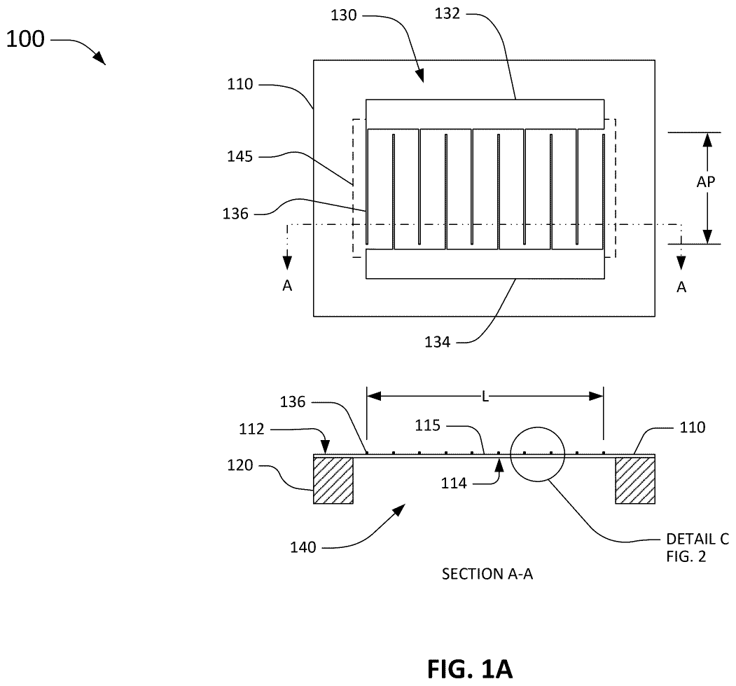

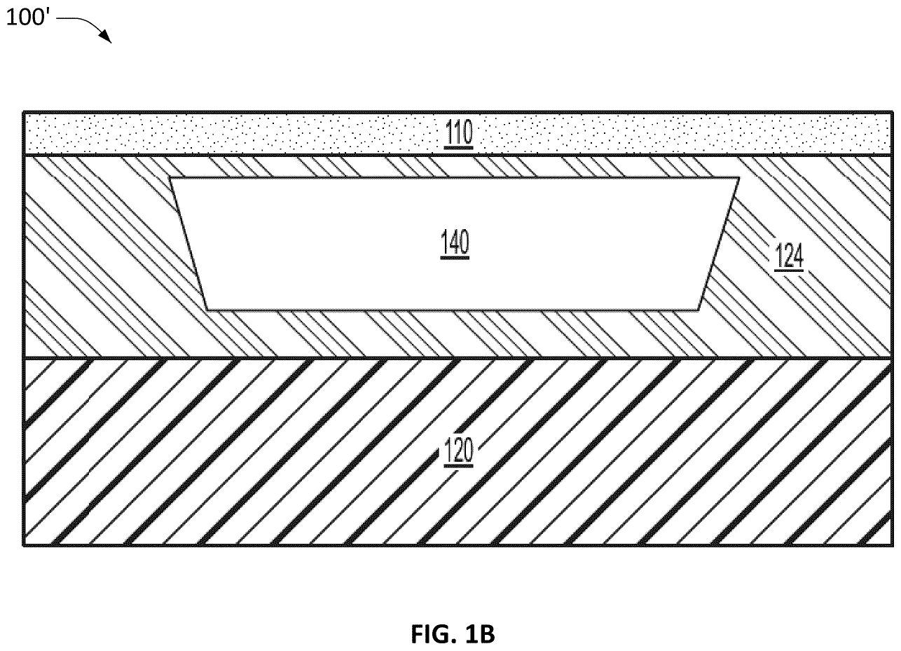

FIG. 1A shows a simplified schematic top view and orthogonal cross-sectional views of a bulk acoustic resonator device, namely a transversely excited film bulk acoustic resonator (XBAR) 100. XBAR resonators, such as the resonator 100, may be used in a variety of RF filters including band-reject filters, band-pass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120−90, 0) and (0, 128-90, 0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

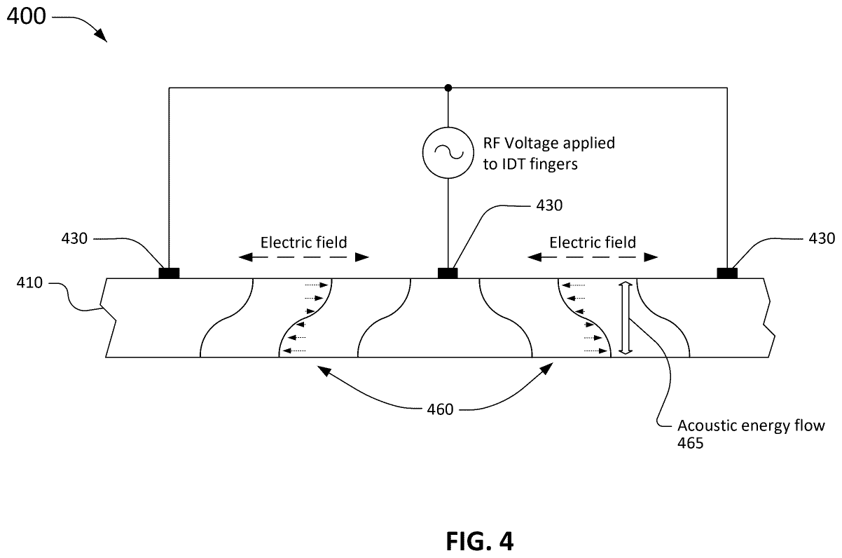

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example SiO₂, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other.

Moreover, in the example of FIG. 1B, the cavity 140 is defined on all sides by the dielectric layer 124. However, in other exemplary embodiments, one or more sides of the cavity 140 may be defined by the substrate 120 or the piezoelectric layer 110. In the example of FIG. 1B, the cavity 140 has a trapezoidal shape. However, as noted above, cavity shape is not limited and may be rectangular, oval, or other shapes.

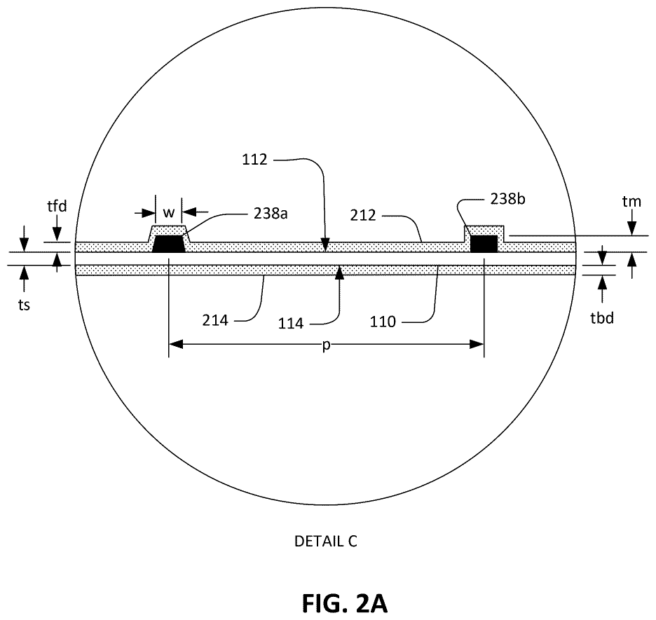

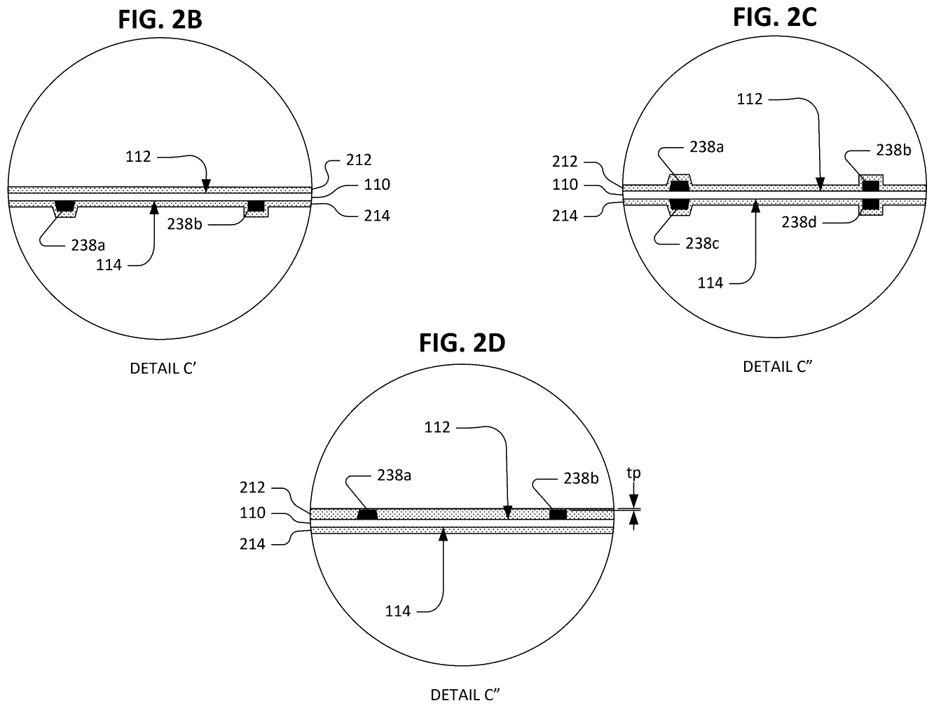

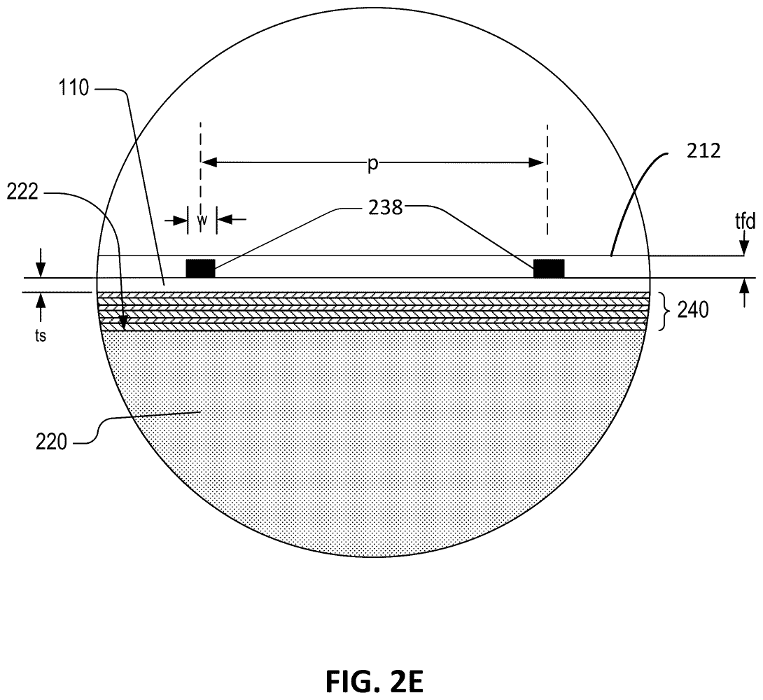

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nanometers (nm) to 1500 nm. When used in filters for 5G NR and Wi-Fi™ bands from 3.4 GHz to 7 GHz, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between a pair of adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. In some cases, the center-to-center spacing is constant in individual sections comprising at least 3 adjacent IDT fingers. In this case, the pitch of a section may refer to an average pitch of the section, while the pitch of the entire IDT may refer to the average pitch across all sections of the IDT. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 238 are visible) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a bulk shear wave. In an exemplary aspect, each layer of the acoustic Bragg reflector 240 has a thickness equal to, or about, one-fourth of the wavelength in the layer of a bulk shear wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 238a and 238b, may be disposed on a surface of the front side 112 of the piezoelectric layer 110. Alternatively, IDT fingers, such as IDT finger 238a and 238b, may be disposed in grooves formed in the surface of the front side 112. The grooves may extend partially through the piezoelectric layer. Alternatively, the grooves may extend completely through the piezoelectric layer.

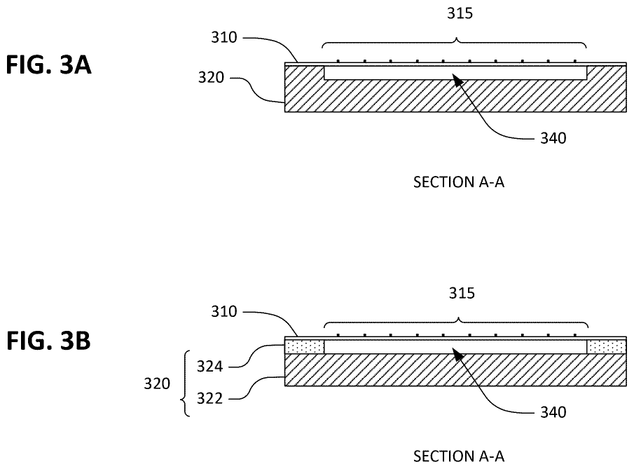

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is primarily lateral (i.e., primarily laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is Defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

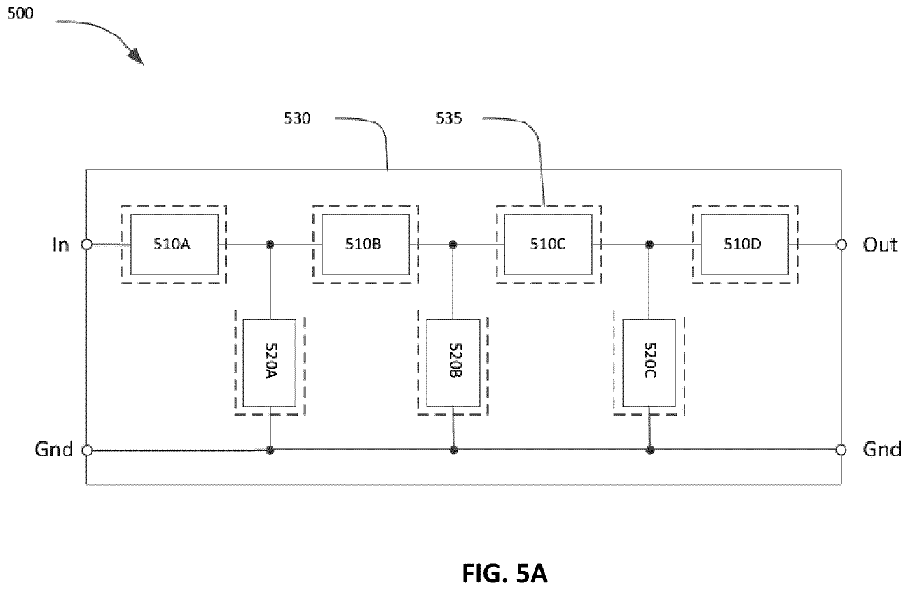

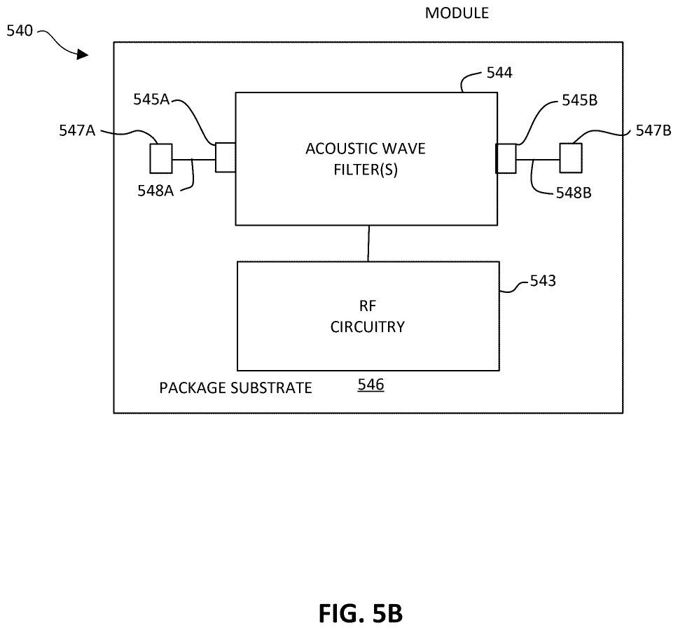

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, which has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, and 510C and the shunt resonators 520A and 520B can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or circuit) 543. In an exemplary aspect, the acoustic wave filters 544 may include one or more of filter 500 including XBARs, as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

In some aspects, to mitigate spurs in a filter passband, thinner IDT fingers (e.g., finger metal electrodes) with a smaller thickness tm may be used in the resonators, such as the bulk acoustic resonators described above. In some examples, using thinner IDT fingers (i.e., shorter IDT fingers with a lower height) may reduce power handling capability as compared to equivalent thick IDT fingers (i.e., taller IDT fingers with a larger height). In an aspect, by identifying “hot spot” regions in the thin metal resonator design with thin IDT fingers and then selectively replacing the thin metal electrodes (e.g., thin or short IDT fingers) in the hot spot regions with equivalent thick IDT fingers (e.g., tall IDT fingers), the power handling performance can be improved without introducing too many thick metal spurs which may otherwise be generated due to the thicker IDT fingers.

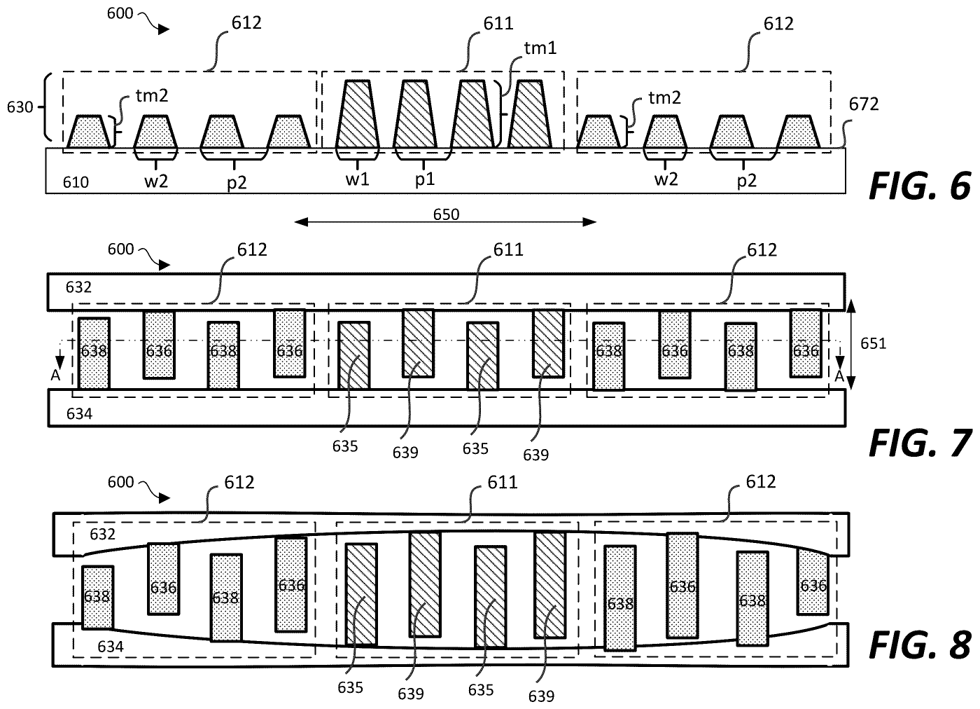

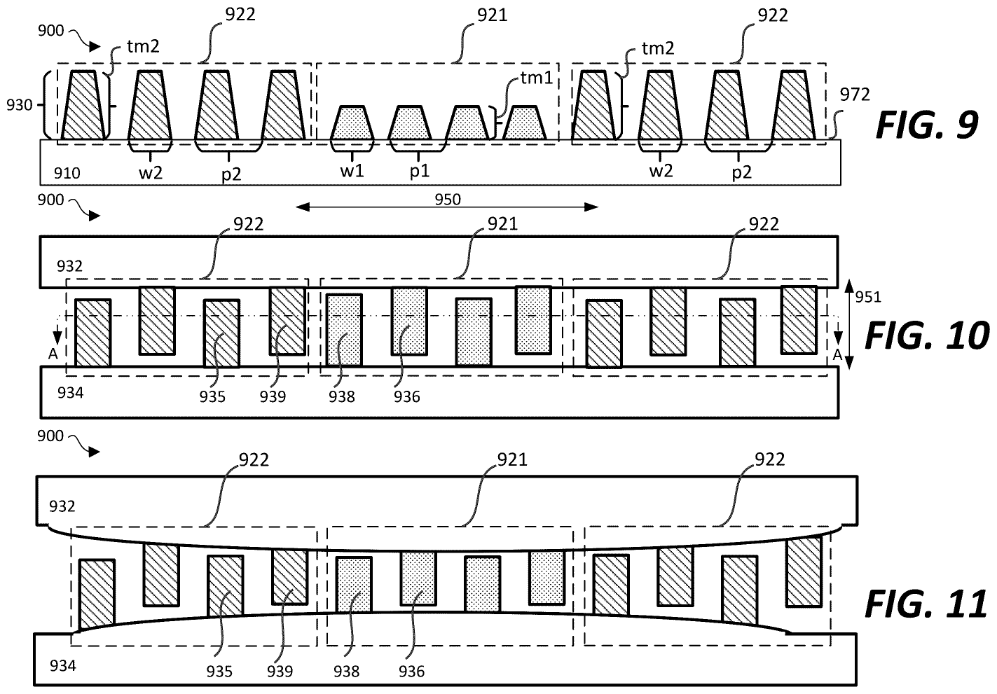

Thus, according to an aspect of the disclosure, a bulk acoustic resonator is provided that includes a piezoelectric layer and an IDT over a surface of the piezoelectric layer. The IDT can include a first plurality of interleaved fingers that are adjacent to each other and a second plurality of interleaved fingers that are adjacent to each other. The second plurality of interleaved fingers can be disposed on each side of the first plurality of interleaved fingers in a lengthwise direction of the IDT. In other words, the second plurality of interleaved fingers can include a pair of subsets or subsections of interleaved fingers that are disposed on opposing sides of the first plurality of interleaved fingers. A first thickness (i.e., a first height) of the first plurality of interleaved fingers can be different from a second thickness (i.e., a second height) of the second plurality of interleaved fingers, such as shown in FIGS. 6 and 9 below, and thus the IDT can be referred to as a mixed thin-thick IDT (e.g., varying IDT thicknesses or varying IDT heights) where thin IDT fingers are mixed (or otherwise combined) with thick IDT fingers. In some examples, a first pitch of the first plurality of interleaved fingers can be different from a second pitch of the second plurality of interleaved fingers.

In an aspect, the first thickness (i.e., the first height) of the first plurality of interleaved fingers is larger than the second thickness (i.e., the second height) of the second plurality of interleaved fingers, such as shown in FIGS. 6-8. The first plurality of interleaved fingers can be referred to as thick IDT fingers or thicker IDT fingers, and the second plurality of interleaved fingers can be referred to as thin IDT fingers or thinner IDT fingers. Moreover, the thickness or height of the IDT fingers can generally be measured in a direction orthogonal or substantially orthogonal to a surface of the piezoelectric layer, such as the thickness tm of IDT finger 238b shown in FIG. 2A and described above.

In an aspect, the first thickness of the first plurality of interleaved fingers is less than the second thickness of the second plurality of interleaved fingers, such as shown in FIGS. 9-11. The first plurality of interleaved fingers can be referred to as thin IDT fingers or thinner IDT fingers, and the second plurality of interleaved fingers can be referred to as thick IDT fingers or thicker IDT fingers.

Referring back to FIG. 2A, an example of the thickness tm of IDT fingers (e.g., the IDT fingers 238a and 238b) and a thickness ts of a piezoelectric layer (e.g., 110) are shown. In an example, the thin IDT fingers may have thickness(es) that are in a range from a1×ts to a2×ts, where ts is the thickness of the piezoelectric layer. In this aspect, a1 and a2 may be less than 1. In an example, a1 is 0.35, and a2 is 0.5. In an example, the thick IDT fingers may have thickness(es) that are larger than or equal to a3×ts, where a3 may be larger than 1. In an example, a3 is 1.2. In an example, the thick IDT fingers may have thickness(es) that are in a range from a4×ts to a5×ts, where a4 and a5 may be larger than 1. In an example, a4 is 1.1 and a5 is 1.3. In an example, a ratio of the thickness of the thick IDT fingers over the thickness of the thin IDT fingers is larger than or equal to a threshold ratio, such as 2.

FIG. 6 shows a cross-sectional view of a portion of a bulk acoustic resonator 600 including an IDT 630, although the individual components of the bulk acoustic resonator 600 are not shown in detail. The resonator of FIG. 6 may have, for example, the XBAR configuration 100 or 100′ including any of the configurations of FIGS. 1A-3B or any combination thereof. Referring to FIG. 6, the IDT 630 can be disposed on and/or over a surface (or a side) 672 of the piezoelectric layer 610. The IDT 630 can include a first plurality of interleaved fingers 611 and a second plurality of interleaved fingers 612. The second plurality of interleaved fingers 612 can be disposed on each side of the first plurality of interleaved fingers 611 in a first direction (also referred to as a lengthwise direction) 650 of the IDT 630. In an exemplary aspect, the first plurality of interleaved fingers 611 can be disposed in a center portion of the IDT and the second plurality of interleaved fingers 612 can be two sets (e.g., subsets or a pair of subsections) of interleaved fingers that are disposed on each side of the IDT with the first plurality of interleaved fingers 611 in a center portion therebetween.

The first thickness tm1 of the first plurality of interleaved fingers (e.g., thick IDT fingers) 611 is larger than the second thickness tm2 of the second plurality of interleaved fingers (e.g., thin IDT fingers) 612, such that IDT 630 is configured as a mixed thin-thick IDT. Referring to FIG. 6, in an example, the first thickness tm1 can be larger than or equal to two times of the second thickness tm2. As also shown, the second plurality of interleaved fingers 612 include two subsets or subsections of interleaved fingers that are on opposing sides of the first plurality of interleaved fingers 611 relative to the first direction 650, which corresponds to the lengthwise direction L of the IDT as shown in FIG. 1A as described above.

According to exemplary aspects, parameters (e.g., pitches, widths, thicknesses) of the first plurality of interleaved fingers 611 and/or the second plurality of interleaved fingers 612 can be designed or tuned to meet various application conditions and/or requirements including that, for example, the bulk acoustic resonator 600 has a single resonance frequency at the main peak of a passband. In other words, chirping (or variance) of the pitch, the mark, or both, in the IDT of an XBAR can be used to suppress undesirable spurious magnitudes for small signal or large signal performance gains that otherwise depend upon pitch and/or mark, such as metal and propagating modes, with only slight broadening of the primary mode resonance.

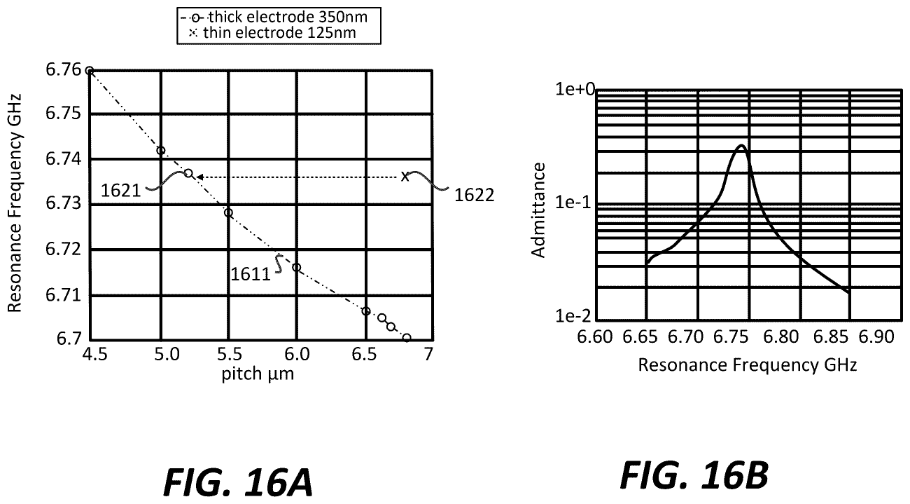

It is noted that in general, IDT chirp is defined by the variation of pitch (e.g., a multi-pitch) or the variation of the mark (e.g., a multi-mark) along the length of the device. In an exemplary aspect, a first pitch p1 of the first plurality of interleaved fingers 611 and a second pitch p2 of the second plurality of interleaved fingers 612 can be designed or determined (e.g., “chirped”) such that the bulk acoustic resonator 600 has a single resonance frequency at the main peak of the passband, such as described in detail in FIGS. 16A-16B. Similarly, respective marks (i.e., finger widths) of the first plurality of interleaved fingers 611 and the second plurality of interleaved fingers 612 can also be chirped in a similar manner. The pitch and/or mark chirping can be continuous across each section of the IDT or in sections/subsections. In other words, pitch and/or mark can be chirped across the length of the IDT, but the IDT can also have multiple subsections (e.g., three or more interleaved fingers) that have a constant pitch and/or mark in each particular section.

In the example shown in FIG. 6, each pitch (e.g., the first pitch p1 or the second pitch p2) is measured as an edge-to-edge spacing between adjacent IDT fingers such as a spacing from an outer edge of one finger to an outer edge of an adjacent finger. The first pitch p1 can be measured from an outer edge of a thin finger to an outer edge of an adjacent thin finger. The second pitch p2 can be measured from an outer edge of a thick finger to an outer edge of an adjacent thick finger. The first pitch p1 and/or the second pitch p2 can also be measured using any other suitable methods, such as a center-to-center spacing such as similar or identical to that shown in FIG. 2A. Referring to FIG. 6, the first pitch p1 of the first plurality of interleaved fingers 611 can be less than the second pitch p2 of the second plurality of interleaved fingers 612. In some examples, a ratio of an absolute difference between the first pitch p1 and the second pitch p2 over the first pitch p1 is to satisfy a condition in order for the bulk acoustic resonator 600 to reduce any divergence in the resonance frequency at the main peak of the passband. For example, the ratio of the absolute difference between the first pitch p1 and the second pitch p2 over the first pitch p1 may be between r1 and r2. In an example, r1 is 10%, and r2 is 25%. In an example, r1 is 15%, and r2 is 20%. In an example, the first pitch p1 is between 1.5 to 2.5 microns, and the ratio of the absolute difference between the first pitch p1 and the second pitch p2 over the first pitch p1 is approximately 15%. In an example, the first pitch p1 is between 2.5 to 6 microns, and the ratio of the absolute difference between the first pitch p1 and the second pitch p2 over the first pitch p1 is from approximately 18% to approximately 20%.

As also described above, the pitch (and/or mark) in each section can be chirped and thus vary within these sections of the IDT. In this aspect, the average or median pitch in each section (e.g., between the first plurality of interleaved fingers 611 and the second plurality of interleaved fingers 612) has a larger change than the chirping (or variance) within each section. In other words, each respective section of the first pitch p1 of the first plurality of interleaved fingers 611 and the second pitch p2 of the second plurality of interleaved fingers 612 are chirped within each section at a variance that is less than a variance between the first pitch p1 of the first plurality of interleaved fingers 611 and the second pitch p2 of the second plurality of interleaved fingers 612.

For example, according to an exemplary aspect, r1 is 12% and r2 is 20%, and thus the second pitch p2 is approximately 12% to 20% larger than that of the first pitch p1. In this case, mixing the thick IDT fingers 611 spaced at the first pitch p1 apart and the thin IDT fingers 612 spaced at the second pitch p2 apart in the bulk acoustic resonator 600 where p2 is approximately 12% to 20% larger than p1 can significantly mitigate spurs in the filter passband, reduce the divergence in the resonance frequency at the main peak of the filter passband, and maintain power handling performance. Moreover, the pitch in each section can be constant or the pitch can be chirped within each section (e.g., interleaved fingers 611 and interleaved fingers 612) and have a smaller change (e.g., 1% to 8%) within such sections.

FIGS. 7-8 show top views of respective examples of the bulk acoustic resonator 600 according to exemplary aspects of the disclosure. Referring to FIGS. 7-8, the IDT 630 can include a first busbar 632 and a second busbar 634 that are disposed on the surface 672 (not shown in FIGS. 7-8) of the piezoelectric layer 610 (not shown in FIGS. 7-8) and extend along the first direction 650. It should be appreciated that these busbars can generally correspond to busbars 132 and 134 of FIG. 1A in an exemplary aspect as described above. Moreover, the first direction 650 can be substantially orthogonal to a second direction 651 in which the first plurality of interleaved fingers 611 and the second plurality of interleaved fingers 612 of the IDT 630 extend. Alternatively, the interleaved fingers can extend in a skewed configuration relative to the respective busbars, for example, at an obtuse or acute angle.

According to the exemplary aspect, a first subset of the first plurality of interleaved fingers 611 and the second plurality of interleaved fingers 612 can extend from the first busbar 632, and a second subset of the first plurality of interleaved fingers 611 and the second plurality of interleaved fingers 612 can extend from the second busbar 634. For example, the first subset includes fingers 636 and 639, and the second subset includes fingers 635 and 638.

It should be appreciated that the first busbar 632 and the second busbar 634 can have any suitable shape(s). In the example shown in FIG. 7, the first busbar 632 and the second busbar 634 have a rectangular shape. In the example shown in FIG. 8, the first busbar 632 and the second busbar 634 have a convex shape.

The first plurality of interleaved fingers 611 and the second plurality of interleaved fingers 612 can have any suitable length along the second direction 651. In the example shown in FIG. 7, the first plurality of interleaved fingers 611 and the second plurality of interleaved fingers 612 can have a similar or an identical length along the second direction 651. In the example shown in FIG. 8, an average length of the first plurality of interleaved fingers 611 can be longer than an average length of the second plurality of interleaved fingers 612 along the second direction 651, for example, the first plurality of interleaved fingers 611 is longer than the second plurality of interleaved fingers 612 along the second direction 651.

In an example, the convex shape in FIG. 8 may facilitate heat dissipation and thus power handling capabilities of the thin IDT fingers 612. For example, the convex shape in FIG. 8 may result in a narrower section (e.g., a shorter distance along the second direction 651 between the first busbar 632 and the second busbar 634) and thus a shorter thermal pass and a smaller thermal resistance for the second plurality of interleaved fingers 612.

Referring back to FIG. 6, the first plurality of interleaved fingers 611 can have any suitable width (also referred to as mark) w1, the second plurality of interleaved fingers 612 can have any suitable width w2. The description of the width w, such as in FIG. 2A, can be applied to the width w1 or the width w2. In an example, the width w1 of the first plurality of interleaved fingers 611 is substantially identical to the width w2 of the second plurality of interleaved fingers 612.

FIG. 9 shows a cross-sectional view of a portion of a bulk acoustic resonator 900 including an IDT 930, although the individual components of the bulk acoustic resonator 900 are not shown in detail. The resonator of FIG. 9 may have, for example, the XBAR configuration 100 or 100′ including any of the configurations of FIGS. 1A-3B or any combination thereof. Referring to FIG. 9, the IDT 930 can be disposed over a surface (or a side) 972 of the piezoelectric layer 910. The IDT 930 can include a first plurality of interleaved fingers 921 and a second plurality of interleaved fingers 922. The second plurality of interleaved fingers 922 can be disposed on each side of the first plurality of interleaved fingers 921 in a first direction (also referred to as a lengthwise direction) 950 of the IDT 930. In an exemplary aspect, the first plurality of interleaved fingers 921 can be disposed in a center portion of the IDT and the second plurality of interleaved fingers 922 can be two sets (e.g., subsets or subsections) of interleaved fingers that are disposed on each side of the IDT with the first plurality of interleaved fingers 921 in a center portion therebetween.

The first thickness tm1 of the first plurality of interleaved fingers (e.g., thin IDT fingers) 921 is less than the second thickness tm2 of the second plurality of interleaved fingers (e.g., thick IDT fingers) 922, such that the IDT 930 is configured as a mixed thin-thick IDT. Referring to FIG. 9, in an example, the second thickness tm2 is larger than or equal to two times of the first thickness tm1. Thus, comparing the exemplary aspects in FIGS. 6 and 9, one of the first thickness tm1 or the second thickness tm2 can be greater than or equal to two times the other of the first thickness tm1 and the second thickness tm2.

Similar as described above with respect to FIG. 6, a first pitch p1 of the first plurality of interleaved fingers 921 and a second pitch p2 of the second plurality of interleaved fingers 922 can be designed or configured such that the bulk acoustic resonator 900 has a single resonance frequency at the main peak of a passband, such as described in detail below in FIGS. 16A-16B. Referring to FIG. 9, the first pitch p1 of the first plurality of interleaved fingers 921 can be larger than the second pitch p2 of the second plurality of interleaved fingers 922. In some examples, a ratio of an absolute difference between the first pitch p1 of the first plurality of interleaved fingers 921 and the second pitch p2 of the second plurality of interleaved fingers 922 over the second pitch p2 of the second plurality of interleaved fingers 922 may be between r1 and r2 where r1 and r2 are described in FIG. 6. In an example, r1 is 10%, and r2 is 25%. In an example, r1 is 15%, and r2 is 20%. In an example, the second pitch p2 of the second plurality of interleaved fingers 922 is between 1.5 to 2.5 microns, and the ratio of the absolute difference between the first pitch p1 and the second pitch p2 over the second pitch p2 is approximately 15%. In an example, the second pitch p2 is between 2.5 to 6 microns, and the ratio of the absolute difference between the first pitch p1 and the second pitch p2 over the second pitch p2 is from approximately 18% to approximately 20%.

FIGS. 10-11 show top views of respective examples of the bulk acoustic resonator 900 according to aspects of the disclosure. Referring to FIGS. 10-11, the IDT 930 can include a first busbar 932 and a second busbar 934 that are disposed on the surface 972 of the piezoelectric layer 910 and extend along the first direction 950. It should be appreciated that the surface 972 and the piezoelectric layer 910 are not shown in FIGS. 10-11 for purposes of brevity. The first direction 950 can be substantially orthogonal to a second direction 951 in which the first plurality of interleaved fingers 921 and the second plurality of interleaved fingers 922 of the IDT 930 extend. A first subset of the first plurality of interleaved fingers 921 and the second plurality of interleaved fingers 922 can extend from the first busbar 932, and a second subset of the first plurality of interleaved fingers 921 and the second plurality of interleaved fingers 922 can extend from the second busbar 934. For example, the first subset includes fingers 936 and 939, and the second subset includes fingers 935 and 938.

As described above, the first busbar 932 and the second busbar 934 can have any suitable shape(s). In the example shown in FIG. 10, the first busbar 932 and the second busbar 934 have a rectangular shape. In the example shown in FIG. 11, the first busbar 932 and the second busbar 934 have a concave shape.

The first plurality of interleaved fingers 921 and the second plurality of interleaved fingers 922 can have any suitable length along the second direction 951. In the example shown in FIG. 10, the first plurality of interleaved fingers 921 and the second plurality of interleaved fingers 922 can have a similar or an identical length along the second direction 951. In the example shown in FIG. 11, an average length of the first plurality of interleaved fingers 921 can be less than an average length of the second plurality of interleaved fingers 922 along the second direction 951, for example, the first plurality of interleaved fingers 921 is less than the second plurality of interleaved fingers 922 along the second direction 951.

In an example, the concave shape in FIG. 11 may facilitate heat dissipation and thus power handling capabilities of the thin IDT fingers 921. For example, the concave shape in FIG. 11 may result in a narrower section (e.g., a shorter distance along the second direction 951 between the first busbar 932 and the second busbar 934) and thus a shorter thermal pass and a smaller thermal resistance for the thin IDT fingers 921.

Referring back to FIG. 9, the first plurality of interleaved fingers 921 can have any suitable width w1, the second plurality of interleaved fingers 922 can have any suitable width w2, such as described in FIG. 6. The description of the width w, such as in FIG. 2A, can be applied to the width w1 or the width w2. In an example, the width w1 of the first plurality of interleaved fingers 921 is substantially identical to the width w2 of the second plurality of interleaved fingers 922.

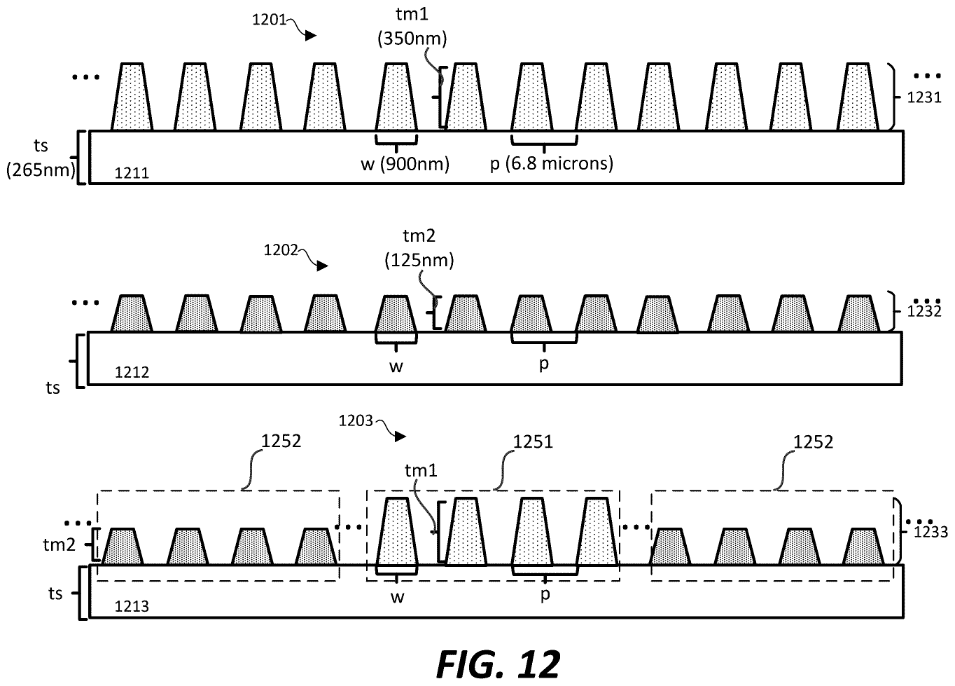

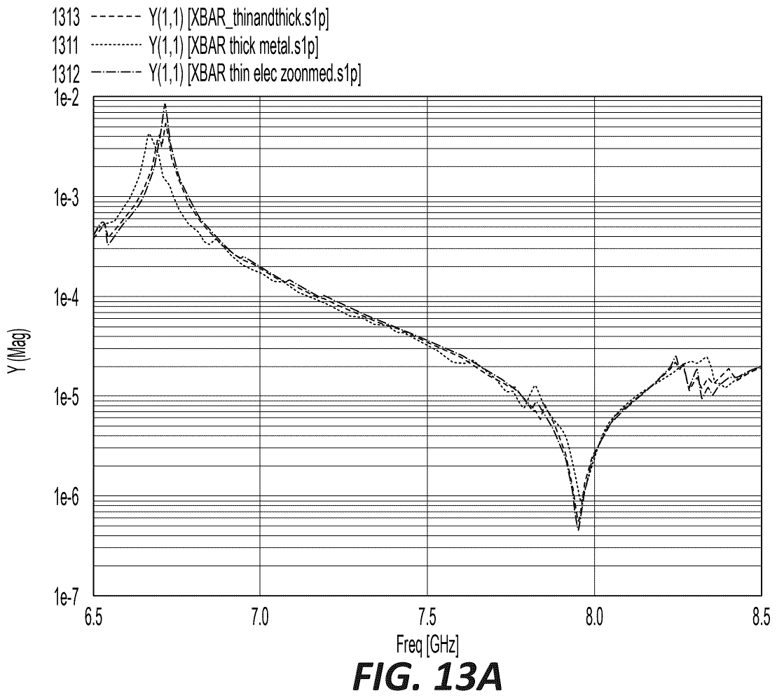

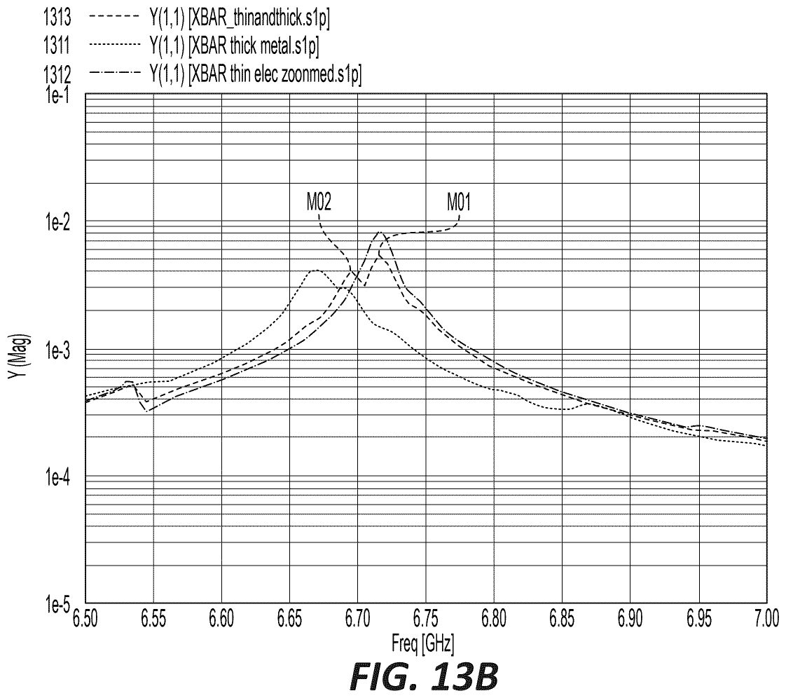

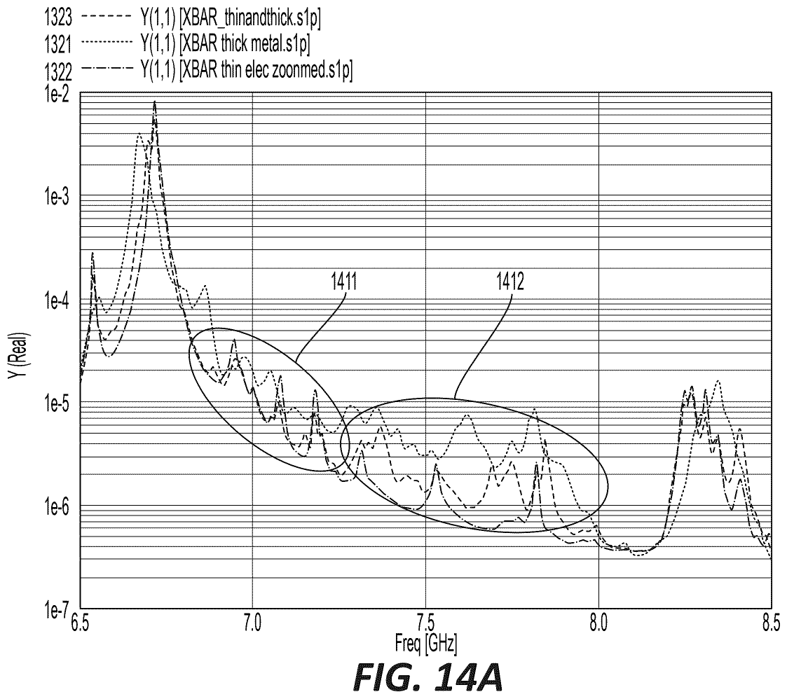

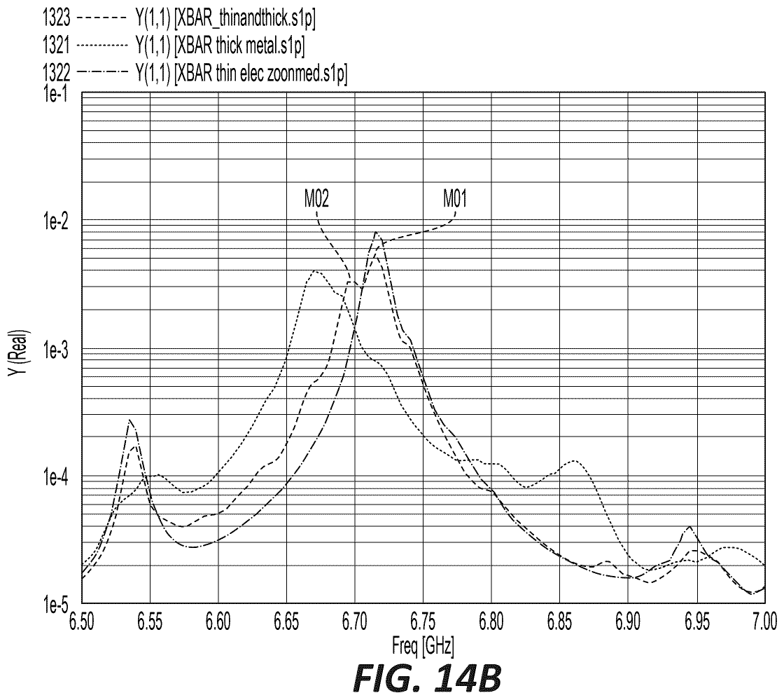

FIG. 12 shows examples three bulk acoustic resonators 1201, 1202, and 1203 having respectively different IDT configurations according to an exemplary aspect. FIGS. 13A-14B compare the performance (including the spur performance) of the three bulk acoustic resonators 1201-1203 with the three respective IDT configurations shown in FIG. 12, for example, simulated using finite element method (FEM) simulation techniques according to an aspect of the disclosure.

Referring to FIG. 12, the three IDT configurations of the respective bulk acoustic resonators 1201-1203 can include a thick metal IDT 1231 over a piezoelectric layer 1211, a thin metal IDT 1232 over a piezoelectric layer 1212, and a mixed thin-thick IDT 1233 over a piezoelectric layer 1213, which can correspond to the exemplary aspects described above. It is again reiterated that the bulk acoustic resonators 1201-1203 of FIG. 12 may have, for example, the XBAR configuration 100 or 100′ including any of the configurations of FIGS. 1A-3B or any combination thereof. In the example shown in FIG. 12, the thick metal IDT 1231, the thin metal IDT 1232, and the mixed thin-thick IDT 1233 are identical except that thicknesses of the thick metal IDT 1231, the thin metal IDT 1232, and the mixed thin-thick IDT 1233 are different. The piezoelectric layers 1211-1213 can be similar or identical to the piezoelectric layer 110, 610, or 910 that is described above.

As shown, the thickness tm1 of the thick metal IDT 1231 is larger than the thickness tm2 of the thin metal IDT 1232. The mixed thin-thick IDT 1233 can be similar to (e.g., correspond to) the IDT 630 where the mixed thin-thick IDT 1233 can include a first plurality of interleaved fingers 1251 having the thickness tm1 and a second plurality of interleaved fingers 1252 having the thickness tm2.

In an example, the parameters used in the simulations include: tm1 is 350 nm, tm2 is 125 nm, a thickness ts of the piezoelectric layers 1211-1213 is 265 nm, the piezoelectric layers 1211-1213 have a 128Y-cut, fingers in the thick metal IDT 1231, the thin metal IDT 1232, and the mixed thin-thick IDT 1233 have a same width w of 900 nm, the thick metal IDT 1231, and the thin metal IDT 1232, and the mixed thin-thick IDT 1233 have a same pitch p of 6.8 microns. Moreover, it should be appreciated that each IDT of the thick metal IDT 1231, the thin metal IDT 1232, and the mixed thin-thick IDT 1233 can include any suitable number of fingers or any suitable pairs of fingers. FIG. 12 shows 6 electrode pairs in each configuration for illustration purposes. In the simulations, the thick metal IDT 1231 includes 24 electrode pairs and the thin metal IDT 1232 includes 24 electrode pairs. The mixed thin-thick IDT 1233 includes 24 electrode pairs: 8 electrode pairs in the first plurality of interleaved fingers 1251 and 8 electrode pairs that are in the second plurality of interleaved fingers 1252 on each side of the first plurality of interleaved fingers 1251.

FIGS. 13A-14B show admittance (interchangeably referred to as a Y-parameter) of each configuration versus a frequency in unit of giga-Herz (GHz) according to some examples of the disclosure. As noted above, each plot is based on a simulation using finite element method (FEM) simulation techniques.

As shown, FIG. 13A illustrates magnitudes 1311-1313 of the Y-parameters corresponding to the bulk acoustic resonators 1201-1203, respectively, from 6.5 GHz to 8.5 GHz according to an example of the disclosure. FIG. 13B shows a zoomed-in view of the magnitudes 1311-1313 of the Y-parameters corresponding to the bulk acoustic resonators 1201-1203, respectively, from 6.5 GHz to 7 GHz according to an example of the disclosure. Admittance can include a real component (also referred to as conductance) and an imaginary component (also referred to as susceptance). FIG. 14A shows real components 1321, 1322, and 1323 of the Y-parameters corresponding to the bulk acoustic resonators 1201-1203, respectively, from 6.5 GHz to 8.5 GHz according to an example of the disclosure. FIG. 14B shows a zoomed-in view of the real components 1321-1323 of the Y-parameters corresponding to the bulk acoustic resonators 1201-1203, respectively, from 6.5 GHz to 7 GHz according to an example of the disclosure.

Referring to FIG. 14A, in an example, the spur performance of the mixed thin-thick IDT 1233 may be superior to that of the thick IDT 1231 and the spur performance of the mixed thin-thick IDT 1233 may be comparable to that of the thin IDT 1232. For example, in regions 1411 and 1412, spurs associated with the mixed thin-thick IDT 1233 have smaller magnitudes than respective spurs associated with the thick IDT 1231, and thus magnitudes of the spurs can be reduced when thin fingers are used in the mixed thin-thick IDT 1233. In an example, in the region 1411, the spurs associated with the mixed thin-thick IDT 1233 have smaller magnitudes than respective spurs associated with the thin IDT 1232. In an example, in the region 1412, the spurs associated with the mixed thin-thick IDT 1233 have comparable or only slightly larger magnitudes than respective spurs associated with the thin IDT 1232. Accordingly, incorporating thick fingers into the thin IDT 1232 may have omittable effects on the spur performance of the thin IDT 1232 while increasing the power handling capability of the thin IDT 1232. As such, the power handling performance can be improved by using the mixed thin-thick IDT (e.g., 1233 in FIG. 12, the IDT 630 in FIG. 6, the IDT 930 in FIG. 9, or the like) in a bulk acoustic resonator without introducing significant thick metal spurs.

Referring to FIGS. 13B and 14B, a main peak of the magnitude 1311 of the Y-parameter associated with the thick metal IDT 1231 occurs approximately at 6.67 GHz, a main peak of the magnitude 1312 of the Y-parameter associated with the thick metal IDT 1232 occurs approximately at 6.715 GHz, and a main peak of the magnitude 1313 of the Y-parameter associated with the mixed thin-thick IDT 1233 is split into two peaks M01 and M02 approximately at 6.695 GHz (M02) and 6.715 GHz (M01).

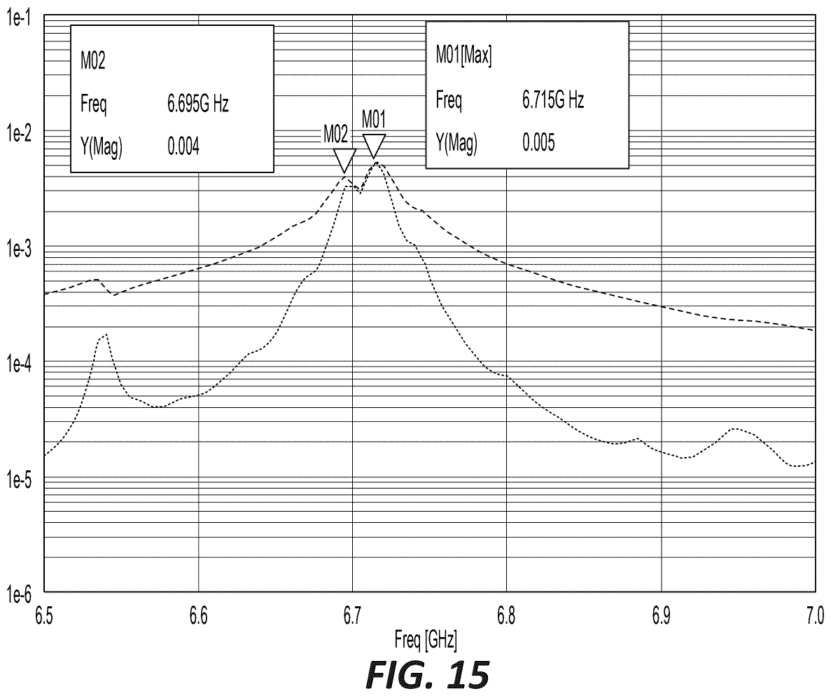

FIG. 15 shows a zoomed-in view of the two peaks M01 and M02 of the magnitude 1313 and the real component 1323 of the Y-parameter associated with the mixed thin-thick IDT 1233 according to an example of the disclosure. In the example shown in FIG. 12, the pitches p of the first plurality of interleaved fingers 1251 and the second plurality of interleaved fingers 1252 are identical, and the widths w of the first plurality of interleaved fingers 1251 and the second plurality of interleaved fingers 1252 are identical. Thus, the magnitude 1313 and the real component 1323 of the Y-parameter associated with the mixed thin-thick IDT 1233 has two peaks M01 and M02.

According to an exemplary aspect of the disclosure, parameters (e.g., the pitches and/or the widths) of the first plurality of interleaved fingers 1251 and the second plurality of interleaved fingers 1252 can vary such that the two peaks (or two resonance frequencies) M01 and M02 can become a single peak (or a single resonance frequency), such as shown in FIGS. 16A-16B.

In an aspect, a pitch of the first plurality of interleaved fingers 1251 (e.g., thick metal IDT or the thick IDT) and/or a pitch of the second plurality of interleaved fingers 1252 (e.g., thin metal IDT or the thin IDT) are changed to match the two resonance frequencies (e.g., M01 and M02) such that the two resonance frequencies (e.g., M01 and M02) become a single peak.

In some examples, the pitch of the first plurality of interleaved fingers 1251 (e.g., the thick metal IDT or the thick IDT) is adjusted to be smaller than the pitch of the second plurality of interleaved fingers 1252 (e.g., the thin metal IDT or the thin IDT) to match the two resonance frequencies.

In some examples, such as in certain design spaces when the thickness of the thick metal IDT is over a threshold (e.g., 1.2×ts), a resonant frequency of the first plurality of interleaved fingers 1251 (e.g., the thick metal IDT or the thick IDT) may be higher than a resonant frequency of the second plurality of interleaved fingers 1252 (e.g., the thin metal IDT or the thin IDT) for a given mark and a given pitch. Thus, the first plurality of interleaved fingers 1251 (e.g., the thick metal IDT or the thick IDT) does not need to have a smaller pitch than the pitch of the second plurality of interleaved fingers 1252 (e.g., the thin metal IDT or the thin IDT) to match the two resonant frequencies. In an example, the pitch of the first plurality of interleaved fingers 1251 is adjusted to be larger than the pitch of the second plurality of interleaved fingers 1252 to match the two resonance frequencies.

FIG. 16A shows a relationship (e.g., indicated by a curve 1611) between a resonance frequency (e.g., in unit of GHz) and a pitch of an IDT (e.g., in unit of microns) according to an aspect of the disclosure. In an example, the IDT in FIG. 16A has a single thickness tm, such as the IDT 1231 or the IDT 1232 shown in FIG. 12. The curve 1611 indicates that the resonance frequency may decrease with the pitch of the IDT. Further, in some examples, a curve indicating a relationship between a resonance frequency and a pitch of a thin IDT is right shifted (e.g., towards a larger pitch) as compared to a curve indicating a relationship between a resonance frequency and a pitch of a thick IDT where the thin IDT and the thick IDT have the same width (or the same mark) w.

In an example, the IDT associated with the relationship indicated by the curve 1611 is a thick IDT having a thickness tm of 350 nm. Referring to FIG. 16A, for the thick IDT having the thickness tm of 350 nm, the pitch p of 5.2 microns, and a width of 900 nm, the resonance frequency is approximately 6.737 GHz as indicated by a point 1621 on the curve 1611. In an example, a thin IDT having a thickness tm of 125 nm can have the same or approximately the same resonance at 6.737 GHz when the thin IDT have the pitch p of 6.8 microns and a width of 900 nm (which is identical to that of the thick IDT) as indicated by a point 1622 in FIG. 16A. The point 1622 is a point on a curve indicating a relationship between a resonance frequency and a pitch of the thin IDT. The curve associated with the thin IDT can be right shifted from the curve 1611.

FIG. 16B shows a simulated result indicating a single peak or a single resonance frequency of a mixed thin-thick IDT including the thin IDT (e.g., having the thickness tm of 125 nm, the pitch p of 6.8 microns, and the width of 900 nm) and the thick IDT (e.g., having the thickness tm of 350 nm, the pitch p of 5.2 microns, and the width of 900 nm) used in FIG. 16A according to an example of the disclosure. In an example, the bulk acoustic resonator 600 can have a single peak such as shown in FIG. 16B. The bulk acoustic resonator 600 can include an IDT with multiple metal thicknesses, such as the first thickness tm1 of the thick IDT fingers 611 and the second thickness tm2 of the thin IDT fingers 612 to improve the power handling performance of a thin metal IDT (e.g., the thin metal IDT 1232) while mitigating the spurs. Further, the fingers in the IDT used in the bulk acoustic resonator 600 can be spaced according to different pitches, for example, the first pitch p1 and the second pitch p2 with a pitch difference of 12-20% such that the resonance frequency of the main peak for the bulk acoustic resonator 600 only has one peak. In the example shown in FIG. 16B, the thicker fingers are positioned in the middle between the thin fingers.

As indicated in FIGS. 16A-16B, for the mixed thin-thick IDT (e.g., the IDT 630, the IDT 930, or the like) to have a single resonance frequency, a pitch of the thin fingers is to be larger than a pitch of the thick fingers, for example, a pitch of the thin fingers is to be approximately 15%-20% larger than a pitch of the thick fingers. Referring back to FIG. 6, the pitches p1 and p2 can be determined (e.g., tuned as described above) so that the IDT 630 has a single main peak, and the main peak does not split into multiple peaks. For example, the two peaks M01 and M02 in FIGS. 13B and 14B can be matched by varying the pitches p1 and p2 for the IDT 630. In an example, tuning the resonance frequency by varying the pitches p1 and p2 may be more beneficial than tuning the resonance frequency by varying the widths w1 and w2 as a higher accuracy of fabrication control can be achieved in controlling the pitches than in controlling the widths.

In an exemplary aspect, referring to FIG. 6, the thickness ts of the piezoelectric layer 610 is 265 nm, the thickness tm1 of the first plurality of interleaved fingers 611 is 350 nm, the thickness tm2 of the second plurality of interleaved fingers 612 is 125 nm, the width w1 of the first plurality of interleaved fingers 611 and the second plurality of interleaved fingers 612 is 900 nm, the first pitch p1 is 5.2 microns, and the second pitch p2 is 6.8 microns. Though specific numeric values are given for the IDT 630, the IDT 630 can be implemented using any suitable combination of numeric values and is not limited to the numeric values in the disclosure.

Referring back to FIG. 9, the pitches p1 and p2 can be configured (e.g., tuned as described above) so that the IDT 930 has a single main peak, similarly as described with respect to the IDT 630. In an example, referring to FIG. 9, the thickness ts of the piezoelectric layer 610 is 265 nm, the thickness tm1 of the first plurality of interleaved fingers 921 is 125 nm, the thickness tm2 of the second plurality of interleaved fingers 922 is 350 nm, the width w1 of the first plurality of interleaved fingers 921 and the second plurality of interleaved fingers 922 is 900 nm, the first pitch p1 is 6.8 microns, and the second pitch p2 is 5.2 microns. Though specific numeric values are given for the IDT 930, the IDT 930 can be implemented using any suitable combinations of numeric values and is not limited to the numeric values in the disclosure.

As described in the disclosure and according to the exemplary aspects, using the mixed thin-thick IDT (e.g., 1233 in FIG. 12, the IDT 630 in FIG. 6, the IDT 930 in FIG. 9, or the like) in a bulk acoustic resonator is provided with improved power handling performance, for example, because the thick IDT fingers (e.g., 611, 922, 1251, or the like) in the mixed thin-thick IDT have a larger power handling capability than using thin IDT fingers alone (e.g., 1232). Further, since a number of the thick IDT fingers (e.g., 611, 922, 1251, or the like) is reduced (e.g., a number of the thick IDT fingers is one third (⅓) of a total number of IDT fingers) from using the thick IDT fingers alone (e.g., 1231) and in some examples the thick IDT fingers (e.g., 611, 922, 1251, or the like) are only used in the “hot spot” regions, the spur performance of the mixed thin-thick IDT may be comparable or only slightly worse than that of the thin IDT, such as shown in simulated results in FIGS. 14A-14B. Thus, benefits of using the mixed thin-thick IDT may include the benefits of the thin IDT (relatively small spurs) and the thick IDT (relatively larger power handling capability).

Further, as described with respect to FIGS. 6, 9, 16A, and 16B, by designing and configurating the parameters (e.g., the pitches p1 and p2) for the mixed thin-thick IDT, the mixed thin-thick IDT may have a single resonance frequency similar to that of the thin IDT or the thick IDT.

In general, the bulk acoustic resonators 600 or 900 can have the configuration shown above with respect to bulk acoustic resonator 100 of FIG. 1A or 100′ in FIG. 1B. Moreover, the bulk acoustic resonator 600 or 900 may be implemented according to the various aspects in FIGS. 1A to 3B. Moreover, the interleaved extend orthogonally or substantially orthogonally to a pair of respective busbars. It should be appreciated that the busbars may also have a length (e.g., the first direction 650 or 950) that extends farther than the respective interleaved fingers.

Finally, it is noted that as used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A bulk acoustic resonator comprising:
a piezoelectric layer; and
an interdigital transducer (IDT) over a surface of the piezoelectric layer, the IDT comprising a first plurality of interleaved fingers and a second plurality of interleaved fingers,
wherein the second plurality of interleaved fingers includes a pair of subsections of interleaved fingers that are disposed on sides of the first plurality of interleaved fingers in a lengthwise direction of the IDT,
wherein the first plurality of interleaved fingers has a first thickness that is different than a second thickness of the second plurality of interleaved fingers,
wherein the first thickness and the second thickness are each measured in a direction substantially orthogonal to the surface of the piezoelectric layer, and
wherein a first pitch of the first plurality of interleaved fingers is different than a second pitch of the second plurality of interleaved fingers.

2. The bulk acoustic resonator of claim 1, wherein the first thickness of the first plurality of interleaved fingers is greater than the second thickness of the second plurality of interleaved fingers.

3. The bulk acoustic resonator of claim 1, wherein the first thickness of the first plurality of interleaved fingers is less than the second thickness of the second plurality of interleaved fingers.

4. The bulk acoustic resonator of claim 1, wherein either the first thickness or the second thickness is greater than or equal to two times than the other of the first thickness and the second thickness.

5. The bulk acoustic resonator of claim 1, wherein each respective section of the first pitch of the first plurality of interleaved fingers and the second pitch of the second plurality of interleaved fingers are chirped within each section at a variance that is less than a variance between the first pitch of the first plurality of interleaved fingers and the second pitch of the second plurality of interleaved fingers.

6. The bulk acoustic resonator of claim 1, wherein the IDT comprises a first busbar and a second busbar that are disposed on the surface of the piezoelectric layer and extend along a first direction that is substantially orthogonal to a second direction in which the first plurality of interleaved fingers and the second plurality of interleaved fingers of the IDT extend.

7. The bulk acoustic resonator of claim 6, wherein the second pitch of the second plurality of interleaved fingers is between 12% to 20% larger than the first pitch of the first plurality of interleaved fingers.

8. The bulk acoustic resonator of claim 6, wherein the first busbar and the second busbar have a convex shape, the first thickness of the first plurality of interleaved fingers is greater than the second thickness of the second plurality of interleaved fingers, and an average length of the first plurality of interleaved fingers is longer than an average length of the second plurality of interleaved fingers in the second direction.

9. The bulk acoustic resonator of claim 6, wherein the first busbar and the second busbar have a concave shape, the first thickness of the first plurality of interleaved fingers is less than the second thickness of the second plurality of interleaved fingers, and an average length of the first plurality of interleaved fingers is shorter than an average length of the second plurality of interleaved fingers in the second direction.

10. The bulk acoustic resonator of claim 1, wherein:
the piezoelectric layer comprises a diaphragm over a cavity, and the IDT is on the diaphragm,
the piezoelectric layer and the IDT are configured such that a radio frequency signal applied to the IDT excites a bulk shear wave having a propagation direction perpendicular to a direction of a primarily laterally excited electric field generated by the IDT, and
the electric field is primarily laterally excited when atomic motion of the bulk shear wave is primarily horizontal in the piezoelectric layer, while the bulk shear wave propagates in a direction primarily perpendicular to the direction of atomic motion.

11. The bulk acoustic resonator of claim 1, wherein the piezoelectric layer is disposed over an acoustic Bragg reflector that includes multiple dielectric layers that alternate between materials having high acoustic impedance and materials having low acoustic impedance.

12. A filter device comprising:
a plurality of bulk acoustic resonators connected in parallel, at least one acoustic resonator of the plurality of bulk acoustic resonators including:
a piezoelectric layer, and
an interdigital transducer (IDT) over a surface of the piezoelectric layer, the IDT comprising a first plurality of interleaved fingers and a second plurality of interleaved fingers,
wherein the second plurality of interleaved fingers includes a pair of subsections of interleaved fingers that are disposed on sides of the first plurality of interleaved fingers in a lengthwise direction of the IDT,
wherein a first thickness of the first plurality of interleaved fingers is different than a second thickness of the second plurality of interleaved fingers,
wherein the first thickness and the second thickness are measured in a direction substantially orthogonal to the surface of the piezoelectric layer, and
wherein a first pitch of the first plurality of interleaved fingers is different than a second pitch of the second plurality of interleaved fingers.

13. The filter device of claim 12, wherein the first thickness of the first plurality of interleaved fingers is greater than the second thickness of the second plurality of interleaved fingers.

14. The filter device of claim 12, wherein the first thickness of the first plurality of interleaved fingers is less than the second thickness of the second plurality of interleaved fingers.

15. The filter device of claim 12, wherein either the first thickness or the second thickness is greater than or equal to two times than the other of the first thickness and the second thickness.

16. The filter device of claim 12, wherein each respective section of the first pitch of the first plurality of interleaved fingers and the second pitch of the second plurality of interleaved fingers are chirped within each section at a variance that is less than a variance between the first pitch of the first plurality of interleaved fingers and the second pitch of the second plurality of interleaved fingers.

17. The filter device of claim 12, wherein the IDT of the at least one acoustic resonator comprises a first busbar and a second busbar that are disposed on the surface of the piezoelectric layer and extend along a first direction that is substantially orthogonal to a second direction in which the first plurality of interleaved fingers and the second plurality of interleaved fingers extend.

18. The filter device of claim 17, wherein the first busbar and the second busbar have a convex shape, the first thickness of the first plurality of interleaved fingers is larger than the second thickness of the second plurality of interleaved fingers, and an average length of the first plurality of interleaved fingers is longer than an average length of the second plurality of interleaved fingers along the second direction.

19. The filter device of claim 17, wherein the first busbar and the second busbar have a concave shape, the first thickness of the first plurality of interleaved fingers is less than the second thickness of the second plurality of interleaved fingers, and an average length of the first plurality of interleaved fingers is shorter than an average length of the second plurality of interleaved fingers along the second direction.

20. A radio frequency module comprising:
a filter device including a plurality of bulk acoustic resonators connected in parallel; and
a radio frequency circuit coupled to the filter device, the filter device and the radio frequency circuit being enclosed within a common package,
wherein at least one acoustic resonator of the plurality of bulk acoustic resonators of the filter device includes:
a piezoelectric layer, and
an interdigital transducer (IDT) over a surface of the piezoelectric layer, the IDT comprising a first plurality of interleaved fingers and a second plurality of interleaved fingers,
wherein the second plurality of interleaved fingers includes a pair of subsections of interleaved fingers that are disposed on sides of the first plurality of interleaved fingers in a lengthwise direction of the IDT,
wherein a first thickness of the first plurality of interleaved fingers is different than a second thickness of the second plurality of interleaved fingers,
wherein the first thickness and the second thickness are measured in a direction substantially orthogonal to the surface of the piezoelectric layer, and
wherein a first pitch of the first plurality of interleaved fingers is different than a second pitch of the second plurality of interleaved fingers.
